(19) United States
(12) Patent Application Publication
(10) Pub. No.: US 2026/0369907 A1
(43) Pub. Date: Nov. 19, 2026

(54) TERMINAL STRUCTURE FOR A POWER SEMICONDUCTOR PACKAGING

(71) Applicants: NEXPERIA TECHNOLOGY (SHANGHAI) LTD., Shanghai (CN); NEXPERIA B.V., Nijmegen (NL)

(72) Inventors: Wei GONG, Stockport (GB); Jürgen Hogerl, Munich (DE); Ziliang Shi, Shanghai (CN); Zhao Zhang, Shanghai (CN); Song Cui, Wuxi (CN)

(73) Assignees: NEXPERIA TECHNOLOGY (SHANGHAI) LTD., Shanghai (CN); NEXPERIA B.V., Nijmegen (NL)

(21) Appl. No.: 19/660,317

(22) Filed: Apr. 28, 2026

Related U.S. Application Data
(63) Continuation of application No. PCT/CN2023/129066, filed on Nov. 1, 2023.

(51) Int. Cl. H01R 12/57; H05K 1/181; H05K 3/32

(52) U.S. Cl. CPC H01R 12/57; H05K 1/181; H05K 3/32; H05K 2201/1031; H05K 2201/10522

(57) ABSTRACT

A terminal structure for an IC including a first DC power terminal connecting to a first end of a power substrate portion and a second DC power terminal connecting to the power substrate portion between the first and a second end thereof. The first and second DC power terminal provide DC power to the power substrate portion and a return line for the DC power. The first DC power terminal includes a U-bend structure forming, together with the power substrate portion, a three-layer current overlap when current commutates between the first and second DC power terminal. The three-layer current overlap defines a current flow in first parallel directions. The first and second DC power terminal form a two-layer current overlap when current commutates between the first and second DC power terminal. The two-layer current overlap defines a current flow in second parallel directions different from the first parallel directions.

### CROSS-REFERENCE TO RELATED APPLICATIONS

This application is a continuation of PCT/CN2023/129066 filed on Nov. 1, 2023, the contents of which are incorporated by reference herein in their entirety.

### BACKGROUND

### 1. Field of the Disclosure

The present disclosure relates to a terminal structure for a semiconductor integrated circuit, a power module including the terminal structure, a power semiconductor packaging including the terminal structure, and a method of manufacturing such terminal structure.

### 2. Description of the Related Art

A power module is an integrated package or assembly that contains one or more power semiconductor devices, control circuitry, and/or other components in a compact and often standardized form factor. Power semiconductors, especially power modules, have found versatile applications across several critical sectors. In the domain of electric vehicles (EVs), power modules are used in EV inverters, which convert direct current (DC) from the battery into alternating current (AC) to drive the electric motor. In the field of solar power generation, power modules are used in solar inverters, which convert DC electricity generated by solar panels into grid-compatible AC power. Within industrial variable frequency drives (VFDs), power modules are used in controlling the speed and torque of electric motors across various applications.

The terminal structure of a power module refers to the arrangement and design of the electrical connections or terminals used to interface the power module with an external circuit. The terminal structure plays a crucial role in efficiently transferring power and control signals to and from the power module.

### SUMMARY

A summary of aspects of certain examples disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

According to an aspect of the present disclosure, a terminal structure for a semiconductor integrated circuit (IC) is presented. The terminal structure can include a first DC power terminal arranged to connect to a power substrate portion of the IC at a first end of the power substrate portion. The terminal can further include a second DC power terminal arranged to connect to the power substrate portion of the IC between the first end and a second end of the power substrate portion. One of the first DC power terminal and the second DC power terminal can be arranged to provide DC power to said power substrate portion. The other one of the first DC power terminal and the second DC power terminal can be arranged to provide a return line for said provided DC power. The first DC power terminal can include a U-bend structure forming, together with the power substrate portion, a three-layer current overlap when current commutates between the first DC power terminal and the second DC power terminal. The three-layer current overlap may define a current flow in first substantially parallel directions. The first DC power terminal and the second DC power terminal can form a two-layer current overlap when current commutates between the first DC power terminal and the second DC power terminal. The two-layer current overlap can define a current flow in second substantially parallel directions. The first substantially parallel directions can be different from the second substantially parallel directions.

The power substrate portion can include one or more power substrates.

In an embodiment, the first substantially parallel directions can be substantially parallel to the power substrate portion.

In an embodiment, the second substantially parallel directions can be substantially perpendicular to the first substantially parallel directions.

In an embodiment, the second substantially parallel directions can be at an angle of about 60° to 90° with the first substantially parallel directions.

In an embodiment, the first DC power terminal can include a first feet portion including a plurality of feet oriented in a first of the first parallel directions and arranged to connect to the power substrate portion. The first DC power terminal can further include a first middle portion oriented in a second of the first parallel directions. The first DC power terminal can further include a first top portion oriented in a third of the first parallel directions. The first feet portion can connect to the first middle portion via a first section of the first DC power terminal. The first section can be oriented substantially perpendicular to the first parallel directions. The first middle portion can connect to the first top portion via a second section of the first DC power terminal. The second section can be oriented substantially perpendicular to the first parallel directions. The first feet portion can be shorter in length compared to the first middle portion. The first middle portion can be shorter in length compared to the first top portion.

In an embodiment, the first feet portion, the first middle portion, the first top portion, the first section and the second section are formed as a single component.

In an embodiment, the first top portion includes one or more holes that are visually aligned with the plurality of feet of the first feet portion.

In an embodiment, the second DC power terminal includes a second feet portion including a plurality of feet oriented in a direction substantially parallel to the first of the first parallel directions and arranged to connect to the power substrate portion. The second DC power terminal can further include a second middle portion oriented in a first of the second parallel directions. The second DC power terminal can further include a second top portion oriented in a direction substantially parallel to the third of the first parallel directions. The second middle portion can be oriented in a direction substantially parallel to the second section of the first DC power terminal. The second feet portion can be connected to the second middle portion. The second middle portion can be connected to the second top portion. The second feet portion may be shorter in length compared to the second top portion.

In an embodiment, the second feet portion, the second middle portion and the second top portion are formed as a single component.

In an embodiment, the second section of the first DC power terminal is shorter in length compared to the second middle section of the second DC power terminal.

In an embodiment, at least one semiconductor die is located between the first feet portion of the first DC power terminal and the second feet portion of the second DC power terminal.

In an embodiment, the terminal structure further includes an AC power terminal arranged to connect to the power substrate portion of the IC at the second end of the power substrate portion. The AC power terminal can include a third feet portion comprising a plurality of feet oriented in a direction substantially parallel to the first of the first parallel directions and arranged to connect to the power substrate portion. The DC power terminal can further include a third top portion oriented in a direction substantially parallel to the third of the first parallel directions. The third feet portion can be connected to the third top portion via one or more intermediate portions.

According to an aspect of the present disclosure, a power module is presented. The power module includes a terminal structure having one or more of the above-described features. The power module can further include a power substrate portion connected to the terminal structure. The power module can further include an IC formed on the power substrate portion.

In an embodiment, the power substrate portion includes a plurality of disjunct and laterally arranged power substrates. A first one of the power substrates can be connected to the first DC power terminal of the terminal structure. A second one of the power substrates can be connected to the second DC power terminal of the terminal structure.

According to an aspect of the present disclosure, a power semiconductor packaging is presented. The power semiconductor packaging can include a terminal structure having one or more of the above-described features. The power semiconductor packaging can further include a power substrate portion connected to the terminal structure. The power semiconductor packaging can further include an IC formed on the power substrate portion. The power semiconductor packaging can further include an encapsulation with silicone gel or molding compounds.

According to an aspect of the present disclosure, a method of manufacturing a terminal structure is presented. The terminal structure includes one or more of the above-described features. The method can include mounting a first DC power terminal to a power substrate portion at a first end of the power substrate portion. The method can further include mounting a second DC power terminal to the substrate portion between the first end and a second end of the power substrate portion. The first DC power terminal can include a U-bend structure forming, together with the power substrate portion, a three-layer current overlap when current commutates between the first DC power terminal and the second DC power terminal. The three-layer current overlap can define a current flow in first substantially parallel directions. The first DC power terminal and the second DC power terminal can be mounted such to form a two-layer current overlap when current commutates between the first DC power terminal and the second DC power terminal. The two-layer current overlap can define a current flow in second substantially parallel directions. The first substantially parallel directions can be different from the second substantially parallel directions.

### BRIEF DESCRIPTION OF THE DRAWINGS

Embodiments of the present disclosure will now be described, by way of example only, with reference to the accompanying schematic drawings in which corresponding reference symbol indicate corresponding parts, in which:

FIG. 1 shows a three-dimensional (3D) model of an example terminal structure of the present disclosure.

FIG. 2 shows a two-dimensional (2D) sideview of an example power substrate.

FIG. 3A and FIG. 3B shows a 2D sideview of an example power terminal structure indicating current flows.

FIG. 4A and FIG. 4B show a 2D and 3D model of a terminal structure of the present disclosure.

FIG. 5 shows a 2D side view of a terminal structure of the present disclosure.

FIG. 6A and FIG. 6B show a 2D and 3D model of a first DC power terminal of the present disclosure.

FIG. 7 shows a 2D sideview of an example power terminal of the present disclosure.

FIG. 8 shows a 2D sideview of an example power terminal of the present disclosure.

FIG. 9 shows the steps of an example method of the present disclosure.

The figures are intended for illustrative purposes only, and do not serve as restriction of the scope of the protection as laid down by the claims.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure but is merely representative of various embodiments. While the various aspects of the embodiments are presented in drawings, the drawings are not necessarily drawn to scale unless specifically indicated.

The described embodiments are to be considered in all respects only as illustrative and not restrictive. The scope of the present disclosure is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present disclosure should be or are in any single example of the present disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same example.

Furthermore, the described features, advantages, and characteristics of the present disclosure can be combined in any suitable manner in one or more embodiments. One skilled in the relevant art will recognize, in light of the description herein, that the present disclosure may be practiced without one or more of the specific features or advantages of a particular embodiment. In other instances, additional features and advantages can be recognized in certain embodiments that may not be present in all embodiments of the present disclosure. Reference throughout this specification to “one embodiment” “an embodiment” or similar language means that a particular feature, structure, or characteristic described in connection with the indicated embodiment is included in at least one embodiment of the present disclosure. Thus, the phrases “in one embodiment” “in an embodiment” and similar language throughout this specification may, but do not necessarily, all refer to the same embodiment.

Stray parasitic inductance within power modules, particularly in third-generation semiconductors like silicon carbide (SiC) and gallium nitride (GaN) chips, poses a significant threat by leading to voltage overshoot. The rapid switching speeds of these advanced semiconductors amplify their sensitivity to parasitic inductance.

The culprits behind this parasitic inductance in power modules encompass various components, including copper traces, die top connections (which may include bonding wires, clips, ribbons, and the like), and even terminal connections. When current flows through or commutates between these components, it encounters resistance due to the inherent inductance, resulting in voltage spikes or overshoots. This phenomenon can have adverse consequences, such as damaging sensitive electronic components, reducing overall system efficiency, and potentially causing malfunctions or failures.

Managing stray parasitic inductance has become a critical consideration in the design and engineering of power modules, especially when incorporating high-speed switching semiconductors like SiC and GaN. Strategies like careful layout design, optimized component placement, and the use of snubber circuits or magnetic shielding are employed to mitigate these hazards and ensure the reliable operation of power electronics systems.

The present disclosure presents a solution to optimize the commutation loop stray inductance with an improved terminal structure for a power semiconductor packaging.

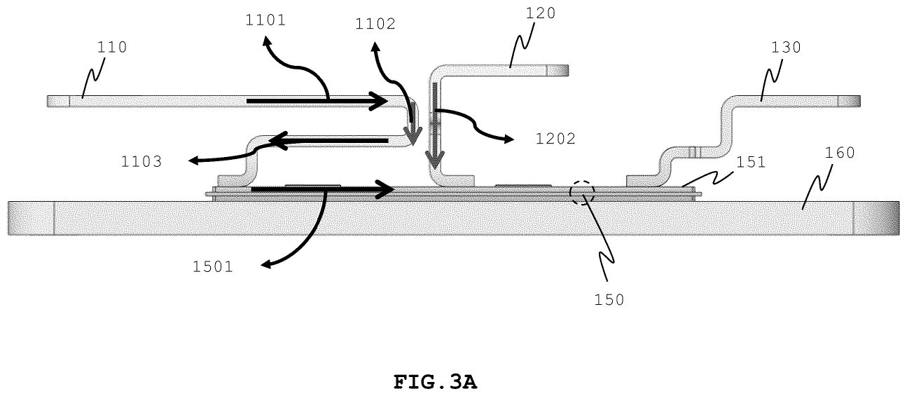

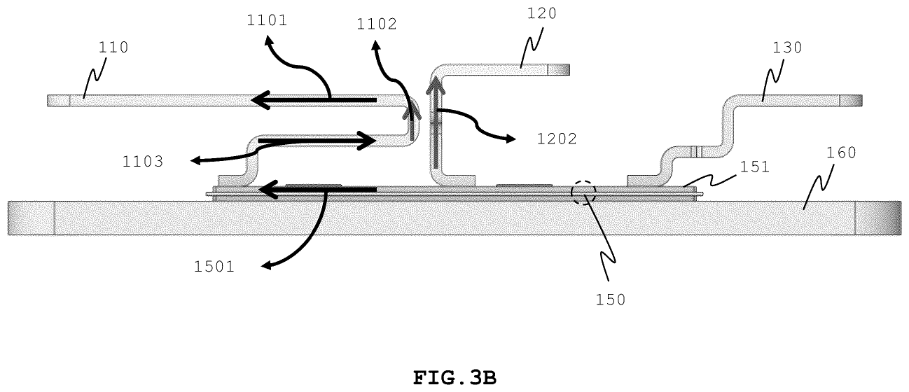

Advantageously, the terminal structure of the present disclosure can reduce commutation loop inductance. Overlapping current paths in parallel direction reduce the overall commutation loop inductance by magnetic field cancellation. FIG. 3A and FIG. 3B, which will be discussed below, show examples of the overlapping current paths in first substantially parallel directions and overlapping current paths in second substantially parallel directions.

The improved terminal structure of the present disclosure includes a U-bend structure (i.e., first power DC terminal) with bends in the same parallel direction making it less complex to manufacture compared to traditional terminals that include neighboring bends in different directions.

Yet another advantage of the improved terminal structure of the present disclosure is that, in the (unlikely) event of a severe malfunction wherein a power semiconductor die may explode, the U-bend structure may cover the dies underneath and act as a protection of the system towards energy generated by “exploding” dies.

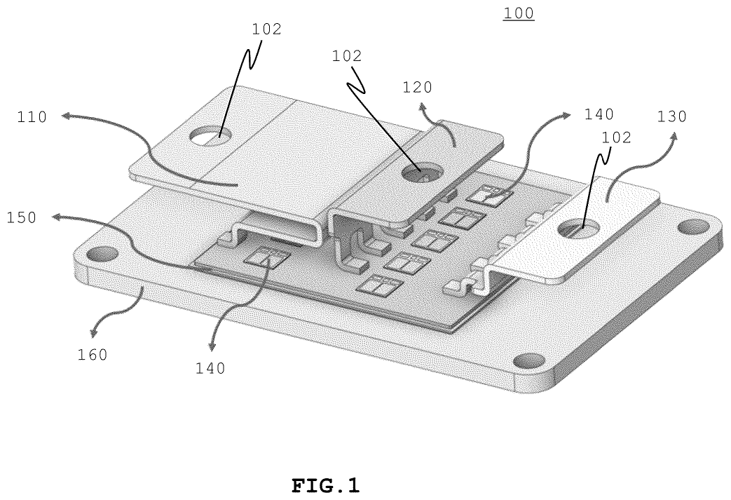

FIG. 1 shows a 3D model of a terminal structure 100 for a power module according to an example embodiment of the present disclosure. Parts 110 and 120 are two power DC terminals, one for positive polarity and the other for negative polarity. The first power DC terminal 110 and the second power DC terminal 120 can be used to connect to a DC link capacitor (not shown). Part 130 is a power terminal for AC output. Numeral 140 represents one or more power semiconductor dies, e.g., silicon insulated-gate bipolar transistor (Si IGBT), SiC metal-oxide-semiconductor field-effect transistor (MOSFET), GaN high electron mobility transistor (HEMT) and/or diode, forming an IC. Part 150 is a power substrate portion, in this example including one power substrate. Part 160 is a baseplate.

The power substrate 150 plays a role by hosting the IC. This IC may be mounted onto the substrate, which often serves as a platform or carrier. Beyond its role as a support structure, the power substrate 150 provides electrical connections to the IC. The power substrate 150 is typically fashioned as a flat board, frequently square or rectangular in shape, and can be crafted from various materials, such as ceramics, printed circuit boards, PCBs, or semiconductive materials.

The terminal connections 110, 120, 130 are the points where external electrical connections are established with the power substrate 150, thereby linking to the IC on the power substrate 150. Within the context described, the first DC power terminal 110 and the second DC power terminal 120 are responsible for delivering the necessary DC power for the IC's operation and establish a return pathway for the DC power. The AC power terminal 130 provides the necessary connectivity for AC signals that may be required for the IC or other components within the module. Together, the terminal connections 110, 120, 130 form a comprehensive frame structure that offers structural integrity, protective enclosure, and efficient electrical connectivity for the integrated circuit while facilitating the supply and return of both DC and AC power or signals as needed for the IC's operation.

For connection to external busbars, one or more holes 102 can be created in the first DC power terminal 110, the second DC power terminal 120 and/or the AC power terminal 130, enabling screw connections, laser welding or other type of connections at the holes 102.

A baseplate 160 may be used for mechanical support. The baseplate 160 can be used for thermal dissipation for which it may be connected to a heat sink (not shown). It is possible that the base plate 160 is not connected to a heat sink, or the baseplate itself acts as a heat sink with cooling structures such as pin-fin structures. In some embodiments, a power module may include a terminal structure of the present disclosure, such as the terminal structure 100 of FIG. 1, without a base plate 160.

The terminal structure 100 is typically encapsulated with silicone gel or molding compounds to form a power semiconductor packaging.

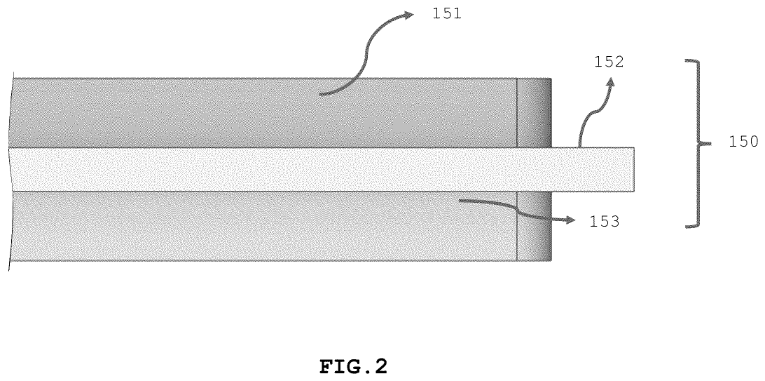

FIG. 2 shows a 2D sideview of an example power substrate 150. The power substrate 150 can be produced using direct bonded copper (DBC) or active metal brazing (AMB) techniques and, in this example, includes three layers: a first copper layer 151, a ceramic layer 152 and a second copper layer 153.

The first copper layer 151 usually includes a pattern to form a circuit for current flow. Partial parts of the power terminals 110, 120, 130, signal terminals (not shown), power semiconductor dies 140, some die top connection parts like bonding wires, clips, ribbons (not shown) and/or possibly other passive components can be bonded to the first copper layer 151 of one or more power substrates 150. The ceramic layer 152 serves primarily as an electrical insulation layer. Non-limiting examples of ceramic materials of the ceramic layer 152 are Si₃N₄, Al₂O₃, AlN, and the like. The second copper layer 153 may facilitate mechanical stress balancing and/or bonding to the baseplate 160.

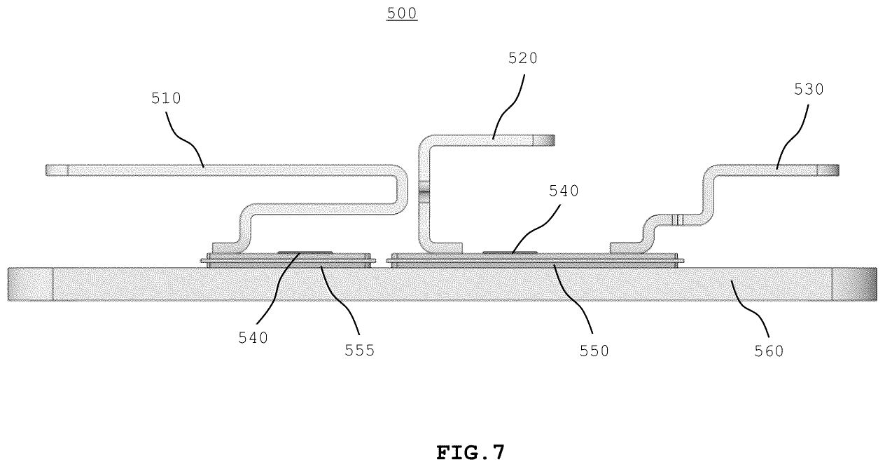

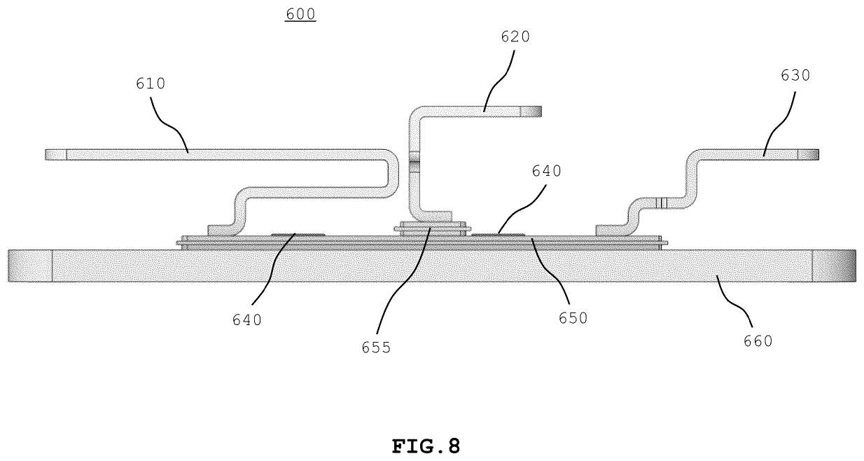

In the example of FIG. 1, the terminal structure 100 includes a power substrate portion including one power substrate 150 arranged along the length direction of the power module. Optionally, the power substrate portion includes more than one power substrate arranged along the length direction of the power module, such as power substrates 550 and 555 in the example of FIG. 7, or relatively small substrates can be arranged on relatively large substrates, such as substrates 650 and 655 in the example of FIG. 8.

FIG. 3A and FIG. 3B indicate current flows through the terminal structure 100. In the example of FIG. 3A, the first DC power terminal 110 is used as a DC+ terminal and the second DC power terminal 120 is used as a DC-terminal. In the example of FIG. 3B, the first DC power terminal 110 is used as a DC-terminal and the second DC power terminal 120 is used as a DC+ terminal. Current flow directions can be both ways as shown in FIG. 3A and FIG. 3B, depending on the switching status.

The arrows 1101, 1103 and 1501 indicate current flows in first substantially parallel directions, wherein the first substantially parallel directions are substantially parallel to the substrate 150. The arrows 1102 and 1202 indicate current flows in second substantially parallel directions, wherein the second substantially parallel directions are different from the first substantially parallel directions. In the examples of FIG. 3A and FIG. 3B, the second substantially parallel directions are substantially perpendicular to the first substantially parallel directions. The current flows 1101, 1102 and 1103 are current flows through the first DC power terminal 110. The current flow 1501 is a current flow at least partly through the power substrate 150. The current flow 1202 is a current flow through the second DC power terminal 120.

The first DC power terminal 110 includes a U-bend structure and is arranged with the second DC power terminal 120 on at least one power substrate 150, forming a three-layer current overlap (1101, 1103 and 1501 in the first substantially parallel directions) and a two-layer current overlap (1102 and 1202 in the second substantially parallel directions) when current flows, e.g., when transistors switch. The three-layer current overlap (1101, 1103, 1501) is formed in the first DC power terminal 110 and the connected substrate upper copper layer 151. The middle current 1103 flows in a different, i.e., opposite but parallel, direction from the other two current flows 1101 and 1501. The two-layer current overlap (1102, 1202) is formed between the first DC power terminal 110 and the second DC power terminal 120. The two currents 1102 and 1202 flow in the same direction.

Between FIG. 3A and FIG. 3B, current flows 1102 and 1202 have opposite but parallel directions. As a result, the magnetic fields have opposite directions in FIG. 3A and FIG. 3B.

The first DC power terminal 110, the second DC power terminal 120 and the AC power terminal 130 can be designed for bonding to one or more substrates 150 based on soldering/sintering bonding technology.

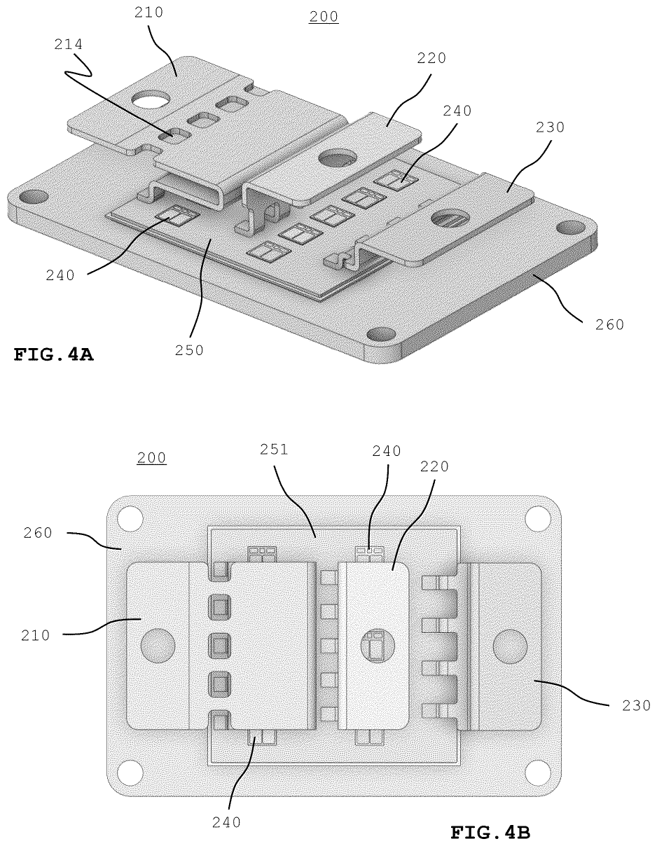

Alternatively, the first DC power terminal, the second DC power terminal and the AC power terminal can be designed for bonding to one or more substrates based on ultrasonic welding (USW) bonding technology. The terminal structure may then be adapted, such as shown in the example of FIG. 4A and FIG. 4B. FIG. 4A shows a 3D model of a terminal structure 200 for a power module according to an example embodiment of the present disclosure. FIG. 4B shows the same terminal structure 200 in a 2D top-view orientation.

Similar to the terminal structure 100 of FIG. 1, the terminal structure 200 of FIG. 4A and FIG. 4B can include a first power DC terminal 210, a second DC power terminal 220, an AC power terminal 230, one or more power semiconductor dies 240, a power substrate 250 and optionally a baseplate 260. The first DC power terminal 210 can include holes 214 that are aligned with terminal feet 212, enabling USW equipment to reach the terminal feet 212 through the holes 214 for USW bonding the terminal feet 212 to the first copper layer 251 of the power substrate 250. Terminal feet 222 of the second DC power terminal 220 can bend in an opposite but parallel direction to the top part of the second DC power terminal 220, enabling the USW equipment to reach the terminal feet 222 as well.

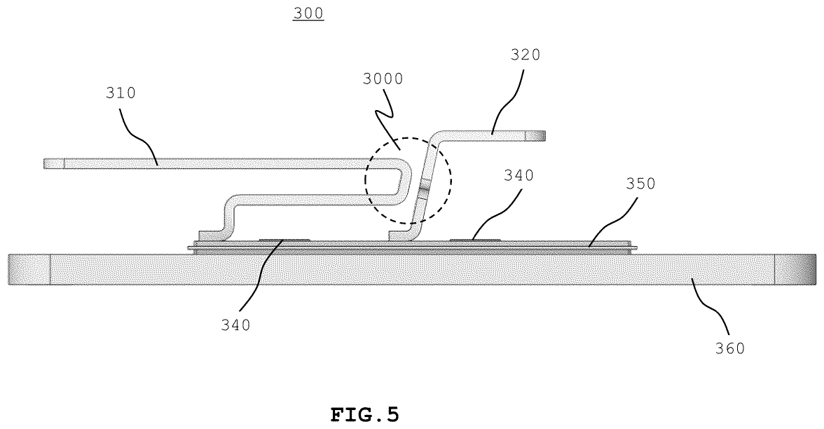

In the examples of FIG. 3A and FIG. 3B, the second substantially parallel directions are substantially perpendicular to the first substantially parallel directions. Alternatively, the first substantially parallel directions and the second substantially parallel directions are different whilst not perpendicular. An example hereof is shown in FIG. 5.

FIG. 5 shows an example of a terminal structure 300, which may be similar to the terminal structure 100 of FIG. 1. Only a first power DC terminal 310, a second DC power terminal 320, a power substrate 350 and a baseplate 360 are shown. In FIG. 3, the two-layer current overlap formed between the first DC power terminal 310 and the second DC power terminal 320, i.e., at the area depicted 3000, is slanted and not perpendicular to the three-layer current overlap formed in the first DC power terminal 310 and the connected upper copper layer of the power substrate 350. The second substantially parallel directions may be at an angle of about 60° to 90° with the first substantially parallel directions.

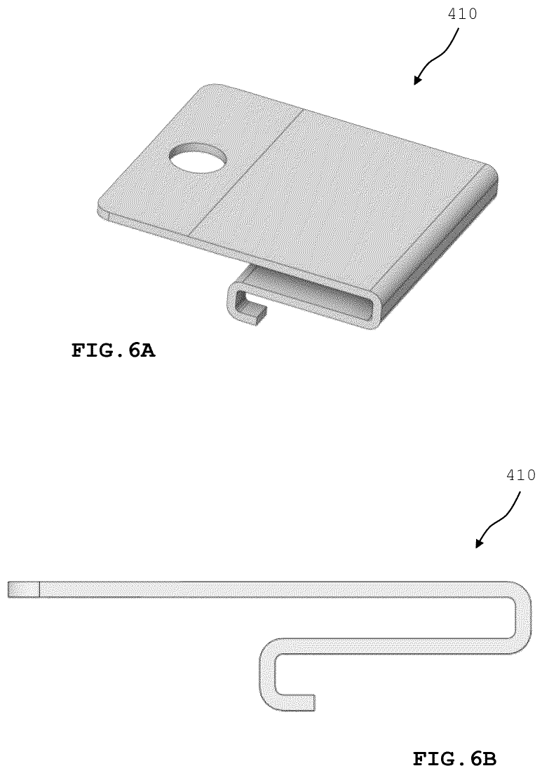

In the example of FIG. 4A and FIG. 4B, the terminal feet 212 of the first DC power terminal 210 are bend in a direction away from the second DC power terminal 220. A similar orientation of the terminal feet of the first DC power terminal can be seen in FIG. 1 and FIG. 5. FIG. 6A (3D) and FIG. 6B (2D sideview) show an alternative feet orientation, wherein the terminal feet 412 of first DC power terminal 410 are bend towards the second DC power terminal. The bending of the terminal feet 412 in a direction opposite to the direction of the terminal feet 212 does not change the three-layer current overlap formed in the first DC power terminal and the connected upper copper layer of the power substrate as shown in FIG. 3A and FIG. 3B.

In the examples of FIG. 1, FIG. 4A and FIG. 5, the terminal structures 100, 200, 300 are shown to include a single power substrate 150, 250, 350. Alternatively, there may be two or more power substrates, an example of which is shown in FIG. 7. Having two or more power substrates may improve temperature cycling reliability.

In the terminal structure 500 of FIG. 7, a first power substrate 550 can connect to the second DC power terminal 520 and to the AC power terminal 530, i.e., through bonding with a first copper layer of the first power substrate 550. A second power substrate 555 can be disjunct from and laterally arranged to the first power substrate 550. The second power substrate 555 can connect to the first DC power terminal 510, i.e., through bonding with a first copper layer of the second power substrate 555.

A smaller substrate or other kind of insulation layers may be arranged on the power substrate, an example of which is shown in FIG. 8. In the terminal structure 600 of FIG. 8, a smaller substrate 655 is arranged on top of the power substrate 650. In the example of FIG. 8, the smaller substrate 655 includes three layers similar to the power substrate 650 and as shown in FIG. 2. The power substrate 650 can connect to the first DC power terminal 610 and to the AC power terminal 630, i.e., through bonding with a first copper layer of the power substrate 650. The smaller substrate 655 can connect to the second DC power terminal 610, i.e., through bonding with a first copper layer of the smaller substrate 655.

The terminal structure may be designed to include one or more smaller substrates, such as smaller substrate 655, or other kind of insulation layers at locations different from the example of FIG. 8 and connect to other elements of the terminal structure.

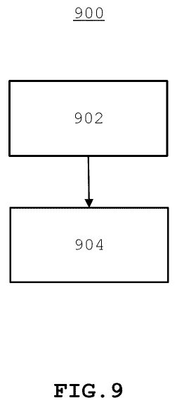

FIG. 9 shows an example process 900 of manufacturing a terminal structure of the present disclosure. In step 902, a first DC power terminal can be mounted to a power substrate portion at a first end of the power substrate portion. In step 904, a second DC power terminal can be mounted to the substrate portion between the first end and a second end of the power substrate portion. The first DC power terminal can include a U-bend structure forming, together with the power substrate portion, a three-layer current overlap when current commutates between the first DC power terminal and the second DC power terminal. The three-layer current overlap defines a current flow in first substantially parallel directions. The first DC power terminal and the second DC power terminal may be mounted such to form a two-layer current overlap when current commutates between the first DC power terminal and the second DC power terminal. The two-layer current overlap defines a current flow in second substantially parallel directions. The first substantially parallel directions can be different from the second substantially parallel directions.

The method may further include any of the steps described with reference to any one of the FIGS. 1-8.

1. A terminal structure for a semiconductor integrated circuit (IC), the terminal structure comprising:
a first direct current (DC) power terminal arranged to connect to a power substrate portion of the IC at a first end of the power substrate portion; and
a second DC power terminal arranged to connect to the power substrate portion of the IC between the first end and a second end of the power substrate portion,
wherein one of the first DC power terminal and the second DC power terminal is arranged to provide DC power to the power substrate portion, and wherein the other one of the first DC power terminal and the second DC power terminal is arranged to provide a return line for the provided DC power,
wherein the first DC power terminal comprises a U-bend structure forming, together with the power substrate portion, a three-layer current overlap when current commutates between the first DC power terminal and the second DC power terminal, wherein the three-layer current overlap defines a current flow in first substantially parallel directions,
wherein the first DC power terminal and the second DC power terminal form a two-layer current overlap when current commutates between the first DC power terminal and the second DC power terminal, wherein the two-layer current overlap defines a current flow in second substantially parallel directions, and
wherein the first substantially parallel directions are different from the second substantially parallel directions.

2. The terminal structure according to claim 1, wherein the first substantially parallel directions are substantially parallel to the power substrate portion.

3. The terminal structure according to claim 2, wherein the second substantially parallel directions are substantially perpendicular to the first substantially parallel directions.

4. The terminal structure according to claim 2, wherein the second substantially parallel directions are at an angle of about 60° to 90° with the first substantially parallel directions.

5. The terminal structure according to claim 1, wherein the first DC power terminal comprises:
a first feet portion comprising a plurality of feet oriented in a first of the first parallel directions and arranged to connect to the power substrate portion;
a first middle portion oriented in a second of the first parallel directions; and
a first top portion oriented in a third of the first parallel directions,
wherein the first feet portion connects to the first middle portion via a first section of the first DC power terminal, the first section being oriented substantially perpendicular to the first parallel directions,
wherein the first middle portion connects to the first top portion via a second section of the first DC power terminal, the second section being oriented substantially perpendicular to the first parallel directions,
wherein the first feet portion is shorter in length compared to the first middle portion, and
wherein the first middle portion is shorter in length compared to the first top portion.

6. The terminal structure according to claim 5, wherein the first feet portion, the first middle portion, the first top portion, the first section and the second section are formed as a single component.

7. The terminal structure according to claim 5, wherein the first top portion comprises one or more holes that are visually aligned with the plurality of feet of the first feet portion.

8. The terminal structure according to claim 5, wherein the second DC power terminal comprises:
a second feet portion comprising a plurality of feet oriented in a direction substantially parallel to the first of the first parallel directions and arranged to connect to the power substrate portion;
a second middle portion oriented in a first of the second parallel directions; and
a second top portion oriented in a direction substantially parallel to the third of the first parallel directions,
wherein the second middle portion is oriented in a direction substantially parallel to the second section of the first DC power terminal,
wherein the second feet portion is connected to the second middle portion,
wherein the second middle portion is connected to the second top portion, and
wherein the second feet portion is shorter in length compared to the second top portion.

9. The terminal structure according to claim 8, wherein the second feet portion, the second middle portion and the second top portion are formed as a single component.

10. The terminal structure according to claim 8, wherein the second section of the first DC power terminal is shorter in length compared to the second middle section of the second DC power terminal.

11. The terminal structure according to claim 8, wherein at least one semiconductor die is located between the first feet portion of the first DC power terminal and the second feet portion of the second DC power terminal.

12. The terminal structure according to claim 1, further comprising an AC power terminal arranged to connect to the power substrate portion of the IC at the second end of the power substrate portion, the AC power terminal comprising:
a third feet portion comprising a plurality of feet oriented in a direction substantially parallel to the first of the first parallel directions and arranged to connect to the power substrate portion;
a third top portion oriented in a direction substantially parallel to the third of the first parallel directions; and
wherein the third feet portion is connected to the third top portion via one or more intermediate portions.

13. A power module comprising:
a terminal structure according to claim 1;
a power substrate portion connected to the terminal structure; and
an integrated circuit (IC) formed on the power substrate portion.

14. The power module according to claim 13, wherein the power substrate portion comprises a plurality of disjunct and laterally arranged power substrates,
wherein the power substrates have a first power substrate that is connected to a first DC power terminal of the terminal structure, and
wherein the power substrates have a second power substrate that is connected to a second DC power terminal of the terminal structure.

15. A power semiconductor packaging comprising:
a terminal structure according to claim 1;
a power substrate portion connected to the terminal structure;
an integrated circuit (IC) formed on the power substrate portion; and
an encapsulation with silicone gel or molding compounds.

16. A method of manufacturing a terminal structure in accordance with claim 1, the method comprising the steps of:
mounting a first direct current (DC) power terminal to a power substrate portion at a first end of the power substrate portion; and
mounting a second DC power terminal to the substrate portion between the first end and a second end of the power substrate portion,
wherein the first DC power terminal comprises a U-bend structure forming, together with the power substrate portion, a three-layer current overlap when current commutates between the first DC power terminal and the second DC power terminal, wherein the three-layer current overlap defines a current flow in first substantially parallel directions,
wherein the first DC power terminal and the second DC power terminal are mounted to form a two-layer current overlap when current commutates between the first DC power terminal and the second DC power terminal, wherein the two-layer current overlap defines a current flow in second substantially parallel directions, and
wherein the first substantially parallel directions are different from the second substantially parallel directions.

17. A power semiconductor packaging comprising:
a terminal structure according to claim 2;
a power substrate portion connected to the terminal structure;
an integrated circuit (IC) formed on the power substrate portion; and
an encapsulation with silicone gel or molding compounds.

18. A power semiconductor packaging comprising:
a terminal structure according to claim 3;
a power substrate portion connected to the terminal structure;
an integrated circuit (IC) formed on the power substrate portion; and
an encapsulation with silicone gel or molding compounds.
